(19) United States
(12) Patent Application Publication
(10) Pub. No.: US 2006/0267198 A1
(43) Pub. Date: Nov. 30, 2006

(54) HIGH PERFORMANCE INTEGRATED CIRCUIT DEVICE AND METHOD OF MAKING THE SAME

(76) Inventors: Mou-Shiung Lin, Hsin-Chu (TW); Chiu-Ming Chou, Kaohsiung (TW); Chien-Kang Chou, Tainan Hsien (TW)

Correspondence Address: NORTH AMERICA INTELLECTUAL PROPERTY CORPORATION, P.O. BOX 506, MERRIFIELD, VA, 22116, US

(21) Appl. No.: 11/420,226

(22) Filed: May 25, 2006

Related U.S. Application Data
(60) Provisional application No. 60/684,815, filed on May 25, 2005.

(51) Int. Cl. H01L 23/48

(52) U.S. Cl. 257/750

(57) ABSTRACT

A new interconnection scheme is described, comprising both coarse and fine line interconnection schemes in an IC chip. The coarse metal interconnection, typically formed by selective electroplating technology, is located on top of the fine line interconnection scheme. It is especially useful for long distance lines, clock, power and ground buses, and other applications such as high Q inductors and bypass lines. The fine line interconnections are suited for local interconnections. The combined structure of coarse and fine line interconnections forms a new interconnection scheme that not only enhances IC speed, but also lowers power consumption.

### CROSS REFERENCE TO RELATED APPLICATIONS

This application claims the benefits of U.S. provisional application No. 60/684,815, filed May 25, 2005.

### BACKGROUND OF THE INVENTION

1. Field of the Invention

The invention relates to the field of high performance integrated circuit devices, and more particularly, to a method of post-passivation processing for the creation of conductive interconnects capable of reducing the parasitic capacitance and resistance of interconnecting wiring on chip.

2. Description of the Prior Art

Improvements in semiconductor device performance are typically obtained by scaling down the geometric dimensions of the integrated circuits, resulting in a decrease in the cost per die, while at the same time some aspects of semiconductor device performance are improved. The metal connections which connect the integrated circuit to other circuit or system components become of relative more importance and have, with the further miniaturization of the IC, an increasingly negative impact on the circuit performance. The parasitic capacitance and resistance of the metal interconnections increase, which degrades the chip performance significantly. Of most concern in this respect is the voltage drop along the power and ground buses and the RC delay of the critical signal paths. Attempts to reduce the resistance by using wider metal lines result in higher capacitance of these wires.

To solve this problem, one approach has been to develop low resistance metal (such as copper) for the wires while low dielectric materials are used in between signal lines. Currently, the metal interconnection networks are constructed under a layer of passivation. However, this approach is associated with some drawbacks such as high parasitic capacitance and high line resistivity, thus degrades device performance, especially for higher frequency applications and for long interconnect lines that are, for instance, used for clock distribution lines. It takes risks to let the fine line interconnect metal carry high current that is typically required for ground busses and for power busses.

In the past, aluminum film was sputtered covering the whole wafer, and then the metal was patterned using photolithography methods and dry and/or wet etching. It is technically difficult and economically expensive to create an aluminum metal line that is thicker than 2 μm due to the cost and stress concerns of blanket sputtering. In recent years, damascene copper metal has become an alternative for IC metal interconnection. In damascene process, the insulator is patterned and copper metal lines are formed within the insulator openings by blanket electroplating copper and chemical mechanical polishing (CMP) to remove the unwanted copper. Electroplating the whole wafer with thick metal creates large stress and carries a very high material (metal) cost. Furthermore, the thickness of damascene copper is usually defined by the insulator thickness, typically chemical vapor deposited (CVD) oxides, which does not offer the desired thickness due to stress and cost concerns. Again it is also technically difficult and economically expensive to create thicker than 2 μm copper lines.

It is desired to provide a method of creating interconnect lines that removes typical limitations that are imposed on the interconnect wires, such as unwanted parasitic capacitances and high interconnect line resistivity. The invention provides such a method. An analogy can be drawn in this respect whereby the currently (prior art) used fine-line interconnection schemes, which are created under a layer of passivation, are the streets in a city; in the post-passivation interconnection scheme of the present invention, the interconnections that are created above a layer of passivation can be considered the freeways between cities.

### SUMMARY OF THE INVENTION

It is one object of the present invention to provide a method for the creation of interconnect metal that allows for the use of thick and wide metal.

Another object of the invention is to provide a method for the creation of interconnect metal that uses thick layer of dielectric such as polymer.

Yet another object of the invention is to provide a method that allows for the creation of long interconnect lines, whereby these long interconnect lines do not have high resistance or introduce high parasitic capacitance.

A still further object of the invention is to create interconnect lines that can carry high current for the power and ground distribution networks.

A still further object of the invention is to create post-passivation interconnect metal that can be created using cost effective methods of manufacturing by creating the interconnect metal on the surface of a layer of passivation.

In accordance with the claimed invention, a new method is provided for the creation of interconnect lines. Fine line interconnects are provided in a first layer of dielectric overlying semiconductor circuits that have been created in or on the surface of a substrate. A layer of passivation is deposited over the layer of dielectric, a thick second layer of dielectric is deposited over the surface of the layer of passivation. Thick and wide interconnect lines are created in the thick second layer of dielectric.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIG. 1 is a cross-sectional diagram illustrating an IC chip in accordance with the present invention;

FIGS. 2-16 are cross sectional views of a first preferred embodiment of the present invention;

FIGS. 3a, 8a and 9a are alternative exemplary embodiments of the structures set forth in FIGS. 3, 8 and 9 respectively;

FIGS. 17-21 are cross sectional views showing exemplary external connections by wire bonding, gold bump or solder bump in the embodiments of the present invention; and

FIGS. 22-24 are cross sectional views of still another preferred embodiment of the present invention.

### DETAILED DESCRIPTION

The present invention discloses a new IC interconnection scheme that is suited for high speed, low power consumption, low voltage, and/or high current IC chips, typically formed on semiconductor wafers. The invention also discloses a post-passivation embossing process, a selective electroplating method to form a thick metal. Incorporating this embossing method, a new interconnection scheme is described, comprising both post-passivation coarse metal interconnection and pre-possivation fine metal interconnection schemes integrated in an IC chip. The coarse metal interconnection, typically formed by selective electroplating technology, is located on top of the fine line interconnection scheme. It is especially useful for long distance lines, clock, power and ground buses, and other applications such as high Q inductors and bypass lines. The fine line interconnections are more appropriate to be used for local interconnections. The combined structure of coarse and fine metal interconnections forms a new interconnection scheme that not only enhances IC speed, but also lowers power consumption.

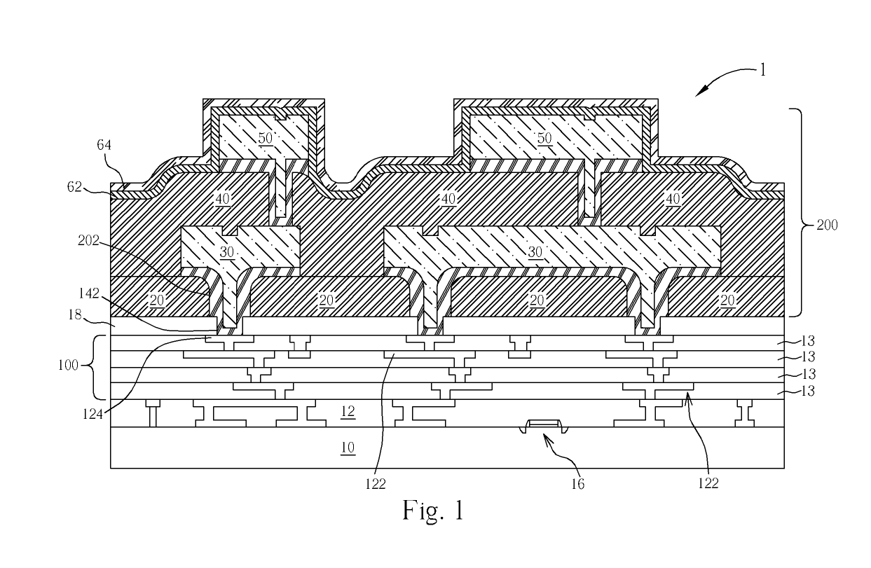

FIG. 1 is a cross-sectional diagram illustrating an IC chip in accordance with the present invention. As shown in FIG. 1, the IC chip 1 comprises a semiconductor substrate 10 such as a silicon substrate, GaAs substrate, SiGe substrate, silicon-on-insulator (SOI) substrate, epitaxial silicon substrate among others. Pre-passivation interconnection scheme 100 is constructed between the semiconductor substrate 10 and a diffusion barrier layer 18 with fine pitch metal wires 122 having a line width/thickness typically less than 3 microns. The manufacturing process of such a pre-passivation interconnection structure may involve the use of damascene process, which deposits a blanket film of metal conductor such as copper or copper alloys on the dielectric layer with trenches or vias formed by micro-lithography processes. The blanket film is then subjected to a planarizing process, such as chemical mechanical polishing (CMP) to remove the unwanted metal material located outside of the trenches. Only the metal body in the trenches or vias remains after the CMP process. In the copper damascene process, the copper is encapsulated by a barrier layer (not explicitly shown) such as Ta, TaN, Ti or TiN. The barrier layer is situated not only underlying the copper, but also surrounding the copper at the sidewalls of the trenches or vias provided in the dielectric layer. Alternatively, the pre-passivation interconnection structure may be formed by sputtering aluminum or an aluminum alloy and patterning the aluminum to form the fine metal lines.

Semiconductor components 16, such as resistors, capacitors, inductors, N/PMOS transistors, CMOS transistors or BiCMOS transistors, are provided on the main surface of the semiconductor substrate 10. These devices are covered with an insulating layer 12 such as silicon oxide or the like

Fine line interconnections 122 are formed within inter-metal dielectric (IMD) layers 13. Preferably, the IMD layers 13 comprise silicon-based oxides, such as silicon dioxide formed by a chemical vapor deposition (CVD) process, CVD TEOS oxide, spin-on-glass (SOG), fluorosilicate glass (FSG), high density plasma CVD oxides, low-k or ultra-low k materials, or a composite layer formed by a portion of this group of materials. The IMD layers 13 typically have a thickness of between about 1000 and 10,000 Angstroms.

The diffusion barrier layer 18 is shown with openings 142 to expose top fine line metal pads 124. The metal pads 124 may be made of copper or aluminum. The diffusion barrier layer is formed of, for example, silicon nitride and functions to prevent the penetration of the transition metal such as gold, copper, silver used in the post-passivation coarse metal scheme into lower layers and device areas. Preferably, the diffusion barrier layer 18 has a thickness of between about 1000 and 5000 Angstroms. The diffusion barrier layer 18 forms a global diffusion layer to protect all of the underlying fine line metal circuitry and devices.

This invention features a post-passivation coarse metal interconnection scheme 200 overlying the diffusion barrier layer 18. The post-passivation coarse metal interconnection scheme 200 includes at least one thick polymer layer and an embossing metal wire or metal pad formed on the polymer layer, wherein the embossing metal wire or metal pad connects with the pre-possivation fine metal interconnection scheme 100 through the polymer layer and diffusion layer.

The thick polymer layer 20 such as polyimide or benzocyclobutene (BCB) is deposited over the surface of diffusion barrier layer 18. Openings 202 are provided in the polymer layer 20. The pattern of opening 202, 182 and 142 aligns with the pattern of the corresponding contact pad 124. Other suitable material for the polymer layer 20 includes silicone elastomer, parylene or teflon, polycarbonate (PC), polysterene (PS), polyoxide (PO), and poly polooxide (PPO). According to the preferred embodiments of this invention, the polymer layer 20 has a thickness of about 5000 angstroms to 30 micrometers. In another case, the polymer layer 20 may be omitted. The thick polymer layer 20 can be coated in liquid form on the surface of the layer 18 or can be laminated over the surface of layer 18 by dry film application. Vias that are required for the creation of conductive plugs can be defined by conventional processes of photolithography or can be created using laser (drill) technology.

Embossing metal wires 30 are formed on the thick polymer layer 20 and fills the opening 202, 182 and 142 to contact the corresponding contact pads 124. According to the preferred embodiments, the embossing metal wires 30 can be formed by additive method. Additional alternating layers of polyimide 40 and metal lines 50 and/or power or ground planes may be added above layers 20 and 30, as needed.

Basic design advantage of the invention is to “elevate” or “fan-out” the fine-line interconnects and to remove these interconnects from the micro and sub-micro level to a metal interconnect level that has considerably larger dimensions and that therefore has smaller resistance and capacitance and is easier and more cost effective to manufacture. This aspect of the application does not include any aspect of pad re-distribution and therefore has an inherent quality of simplicity. It therefore further adds to the importance of the referenced application in that it makes micro and sub-micro wiring accessible at a wide and thick metal level.

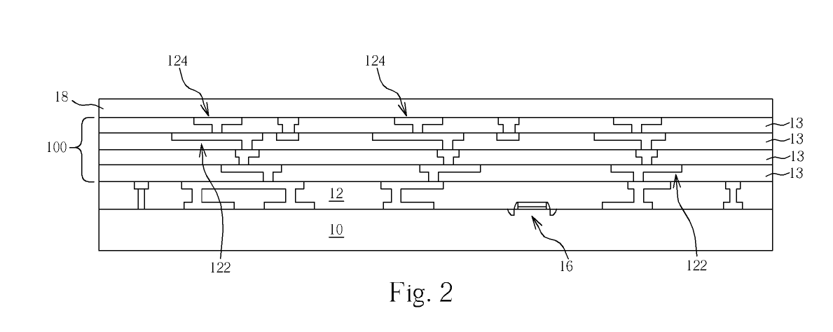

Referring now to FIGS. 2-16 the embossing process of the present invention will be described in detail. The inventive embossing process is a selective deposition process used to form the post-passivation coarse metal interconnection scheme 200. Referring initially to FIG. 2, a semiconductor substrate 10 such as a silicon substrate, GaAs substrate, SiGe substrate, silicon-on-insulator (SOI) substrate, epitaxial silicon substrate is provided. Pre-passivation interconnection scheme 100 is constructed between the semiconductor substrate 10 and a diffusion barrier layer 18 with fine pitch metal wires 122 having a line width/thickness less than 3 microns. The manufacturing process of such a pre-passivation interconnection structure 100 may involve the use of damascene process, which deposits a blanket film of metal conductor such as copper or copper alloys on the dielectric layer with trenches or vias formed by micro-lithography processes. The blanket film is then subjected to a planarizing process, such as chemical mechanical polishing (CMP) to remove the unwanted metal material located outside of the trenches. Only the metal body in the trenches or vias remains after the CMP process. In the copper damascene process, the copper is encapsulated by a barrier layer (not explicitly shown) such as Ta, TaN, Ti or TiN. The barrier layer is situated not only underlying the copper, but also surrounding the copper at the sidewalls of the trenches or vias provided in the dielectric layer. Alternatively, the pre-passivation interconnection structure may be formed by sputtering aluminum or an aluminum alloy and patterning the aluminum to form the fine metal lines.

Semiconductor components 16, such as resistors, capacitors, inductors, N/PMOS transistors, CMOS transistors or BiCMOS transistors, are provided on the main surface of the semiconductor substrate 10. These devices are covered with an insulating layer 12 such as silicon oxide or the like.

Fine line interconnections 122 are formed within inter-metal dielectric (IMD) layers 13. Preferably, the IMD layers 13 comprise silicon-based oxides, such as silicon dioxide formed by a chemical vapor deposition (CVD) process, CVD TEOS oxide, spin-on-glass (SOG), fluorosilicate glass (FSG), high density plasma CVD oxides, low-k or ultra-low k materials, or a composite layer formed by a portion of this group of materials. The IMD layers 13 typically have a thickness of between about 1000 and 10,000 Angstroms.

A diffusion barrier layer 18 is provided. The diffusion barrier layer is formed of, for example, silicon nitride and functions to prevent the penetration of the transition metal such as gold, copper, silver used in the post-passivation coarse metal scheme into the lower layers and device areas. Preferably, the barrier layer 18 has a thickness of between about 500 and 3000 angstroms.

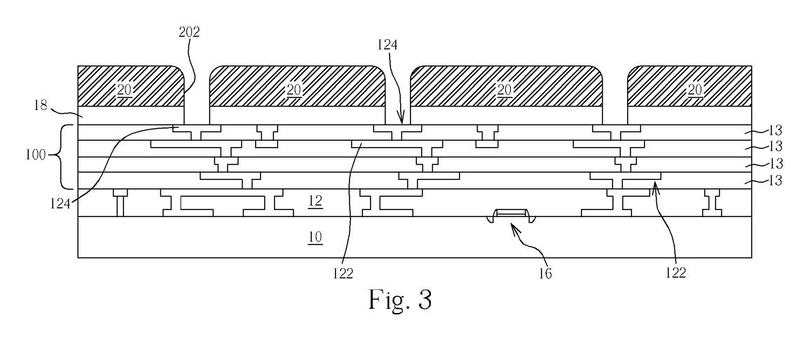

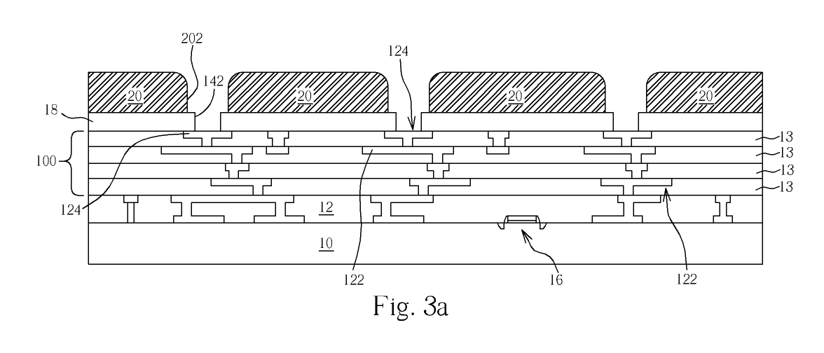

As shown in FIG. 3, a photosensitive polymer layer 20 such as polyimide or benzocyclobutene (BCB) is deposited over the surface of diffusion barrier layer 18 by spin-on, printing or laminating methods. The polymer layer 20 may be multiple coatings or cured. Openings 202 are etched into the polymer layer 20 and the layers 14 and 18 to expose corresponding contact pads 124, which may be copper or aluminum pads. Other suitable material for the polymer layer 20 includes silicone elastomer, parylene or teflon, polycarbonate (PC), polysterene (PS), polyoxide (PO), poly polooxide (PPO) and epoxy-based materials. According to the preferred embodiments of this invention, the polymer layer 20 has a thickness of about 5000 angstroms to 30 micrometers (after curing). In another case, the polymer layer 20 may be omitted. The thick polymer layer 20 can be coated in liquid form on the surface of the layer 18 or can be laminated over the surface of layer 18 by dry film application. Vias that are required for the creation of conductive plugs can be defined by conventional processes of photolithography or can be created using laser (drill) technology.

According to another embodiment, as shown in FIG. 3a, openings 142 are formed in the passivation layer 14 and in the diffusion barrier layer 18 by using a first photolithographic process. The thick polymer layer 20 such as polyimide or benzocyclobutene (BCB) is then deposited over the surface of diffusion barrier layer 18 and fills the openings 142. A second photolithographic process is carried out to form openings 202 in the polymer layer 20 directly above the openings 142. The dimension of the openings 202 is greater than the dimension of the openings 142. Alternatively, the corresponding opening 202 and the opening 142 may be formed in one step. In another case, the opening 202 is formed prior to the formation of the opening 142.

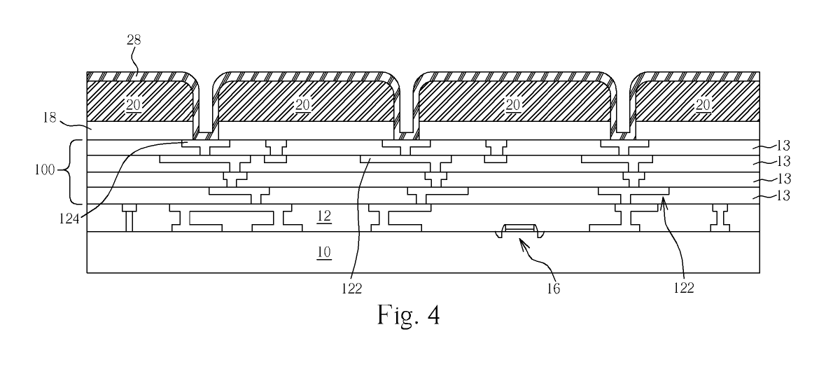

As shown in FIG. 4, an adhesion/barrier/seed layer 28 is deposited over the polymer layer 20 and on the interior surface of the openings 202. The adhesion/barrier/seed layer 28, preferably comprising TiW, TiN, TaN, Ti, Ta, TaN, Au, Cr, Cu, is deposited, preferably by sputtering to a thickness of between about 100 and 5,000 Angstroms. The adhesion/barrier/seed layer 28 comprises a copper seed layer having a thickness of between about 300 and 3,000 Angstroms.

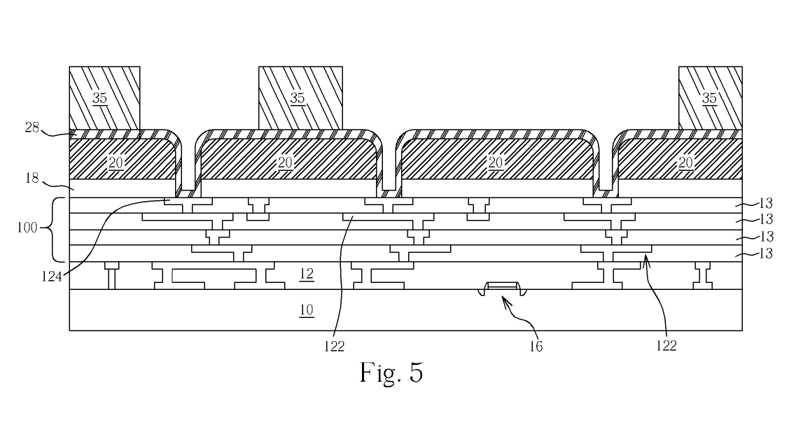

As shown in FIG. 5, a thick photoresist is deposited over the seed layer of the adhesion/barrier/seed layer 28 to a thickness greater than the desired bulk metal thickness. Conventional lithography is used to expose the seed layer in those areas where the coarse metal lines are to be formed, as shown by mask layer 35.

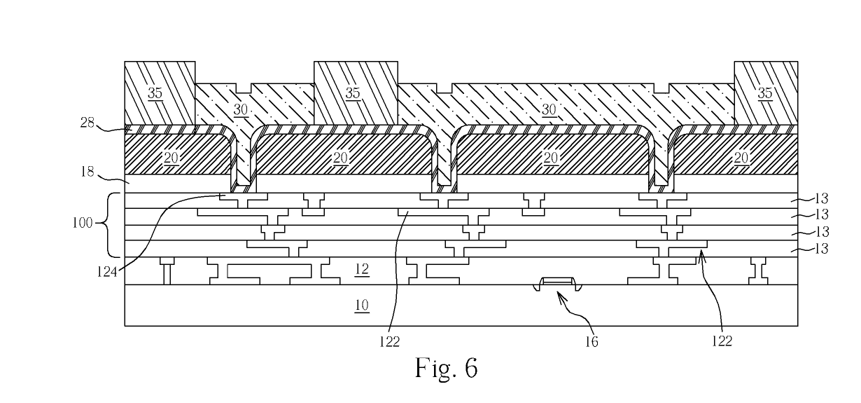

As shown in FIG. 6, an additive metal wire pattern 30 is next formed by electroplating or electroless plating methods, to a thickness of about 1-30 μm, preferably 2-8 μm. The additive metal wire pattern 30 may be gold, copper, Cu/Ni, or silver. In a case that Cu/Ni is used as the additive metal wire pattern 30, the nickel layer has a thickness of about 0.5-5 μm, preferably 1-3 μm. In a case that Au is used as the additive metal wire pattern 30, the Au layer has a thickness of about 1-30 μm, preferably 2-8 μm.

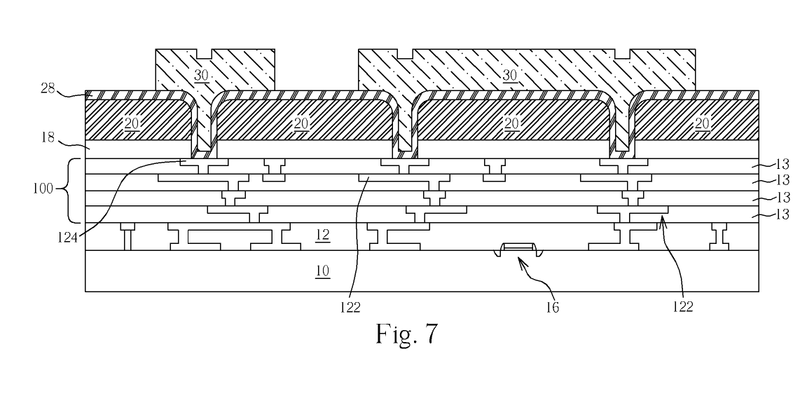

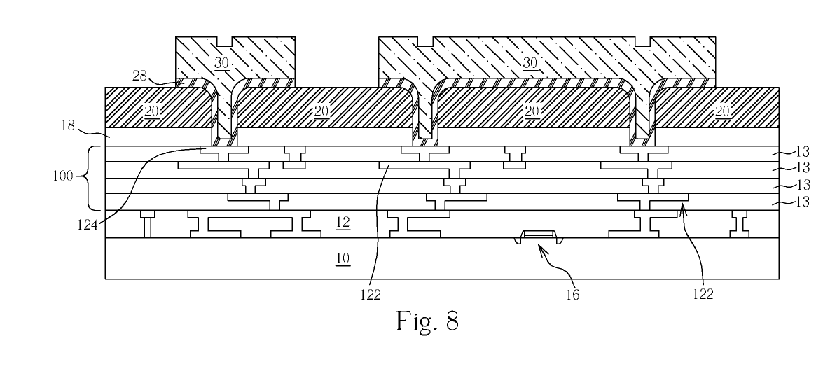

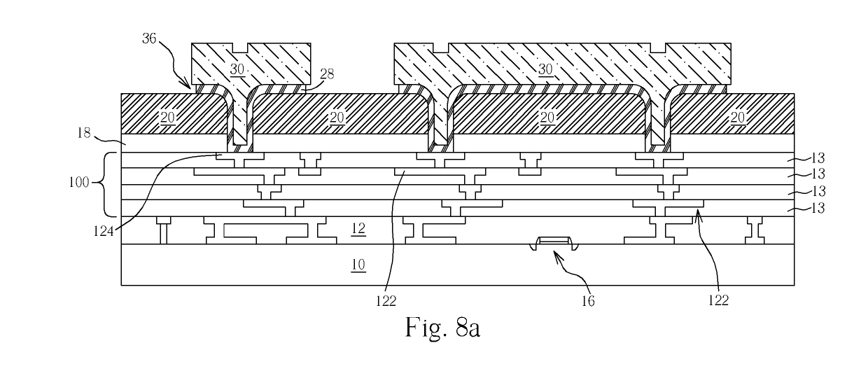

Thereafter, as shown in FIG. 7, the photoresist mask 35 is removed. After removing the photoresist mask 35, as shown in FIG. 8, the adhesion/barrier/seed layer 28 not covered by the additive metal wire pattern 30 is removed by dry etching methods. Alternatively, as shown in FIG. 8a, the adhesion/barrier/seed layer 28 may be etched away by using wet etching, which forms an undercut recess 36 under the additive metal wire pattern 30.

The structure of the coarse metal lines is different from the structure of the fine line metallization. An undercut 36 may be formed in the adhesion/barrier/seed layer 28 during removal of this layer. Furthermore, there is a clear boundary between the sputtered thin seed layer and the electroplated thick bulk metal 30. This can be seen, for example, in a transmission electron microscope (TEM) image. The boundary is due to different grain sizes and/or grain orientation in the two metal layers. For example, in a 1,000-angstrom thick sputtered gold seed layer under a 4-micron thick electroplated gold layer 30, the grain size of the sputtered gold seed layer is about 1,000 angstroms, and the grain boundary is perpendicular to the surface of substrate. The grain size of the electroplated gold 30 is greater than 2 microns with the grain boundary not perpendicular, and typically, at an angle of about 45 degrees from the substrate surface. In the fine line metal interconnections, there is no undercutting or clear boundary of grain size difference inside the aluminum or copper damascene layer.

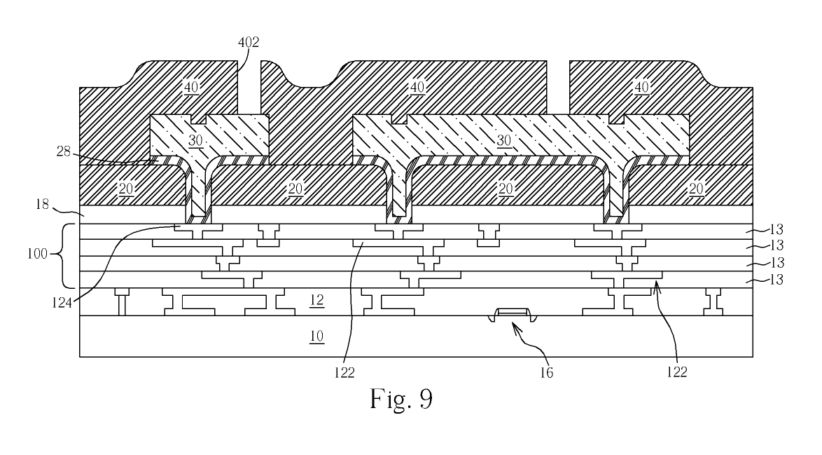

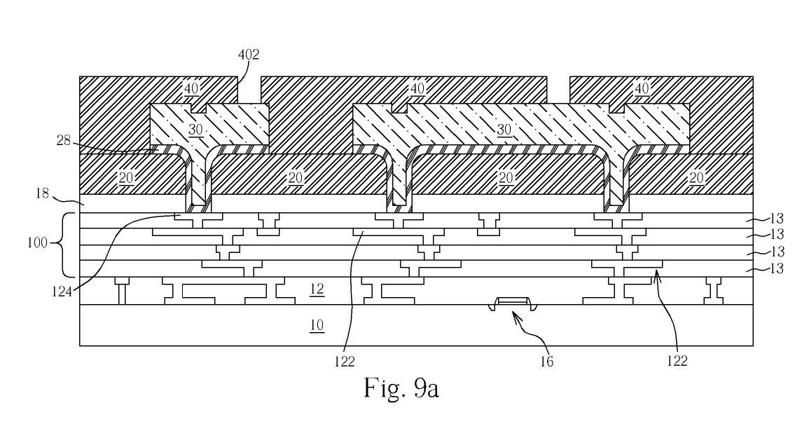

As shown in FIG. 9, after the formation of the metal wire pattern 30, a thick polymer layer 40 such as polyimide or BCB is blanket deposited by spin-on, printing or laminating methods. The polymer layer 40 may be multiple coatings or cured. Openings 402 are etched into the polymer layer 40 to expose metal wire pattern 30. Other suitable material for the polymer layer 40 includes silicone elastomer, parylene or teflon, polycarbonate (PC), polysterene (PS), polyoxide (PO), poly polooxide (PPO) and epoxy-based materials. According to the preferred embodiments of this invention, the polymer layer 40 has a thickness of about 5000 angstroms to 30 micrometers (after curing). The thick polymer layer 40 can be coated in liquid form or can be laminated by dry film application. Openings 402 can be defined by conventional processes of photolithography or can be created using laser (drill) technology.

According to another preferred embodiment, as shown in FIG. 9a, after the deposition or coating of the thick polymer layer 40, a planarization process such as CMP process or other grinding methods can be performed to planarize the thick polymer layer 40. It is advantageous to do so because the bonding pads formed on the thick polymer layer 40 are substantially coplanar, thus improves the reliability during bonding process. Further, the even top surface of the polymer layer 40 can prevent cracking problem of the silicon nitride passivation formed at the last stage.

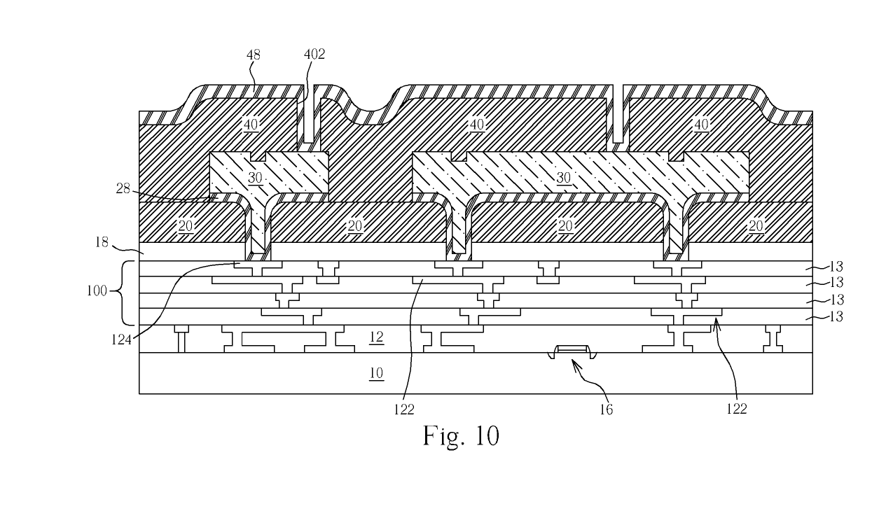

As shown in FIG. 10, an adhesion/barrier/seed layer 48 is deposited over the polymer layer 40 and on the interior surface of the openings 402. The adhesion/barrier/seed layer 48, preferably comprising TiW/Au, Cr/Cu or Ti/Cu, is deposited, preferably by sputtering to a thickness of between about 100 and 5,000 Angstroms. The adhesion/barrier/seed layer 48 comprises a seed layer having a thickness of between about 300 and 3,000 Angstroms.

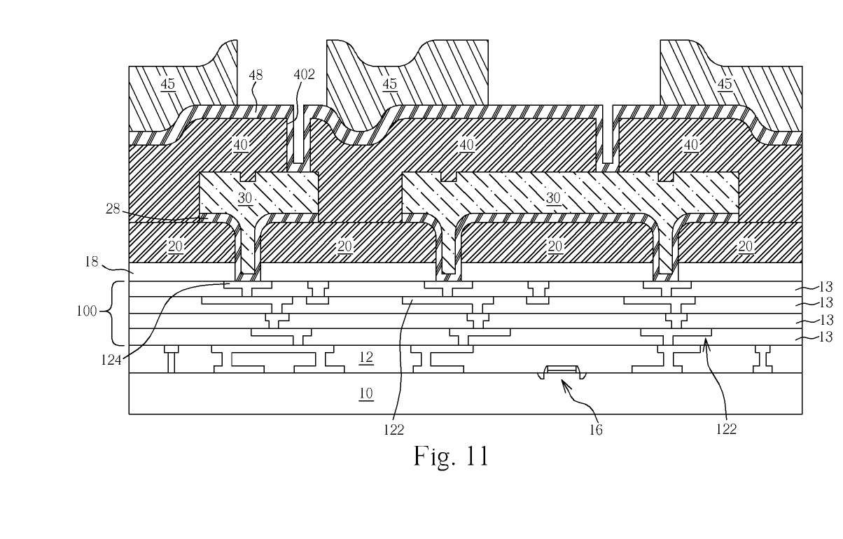

As shown in FIG. 11, a thick photoresist is deposited over the seed layer of the adhesion/barrier/seed layer 48 to a thickness greater than the desired bulk metal thickness. Conventional lithography is used to expose the seed layer in those areas where the coarse metal lines are to be formed, as shown by mask layer 45.

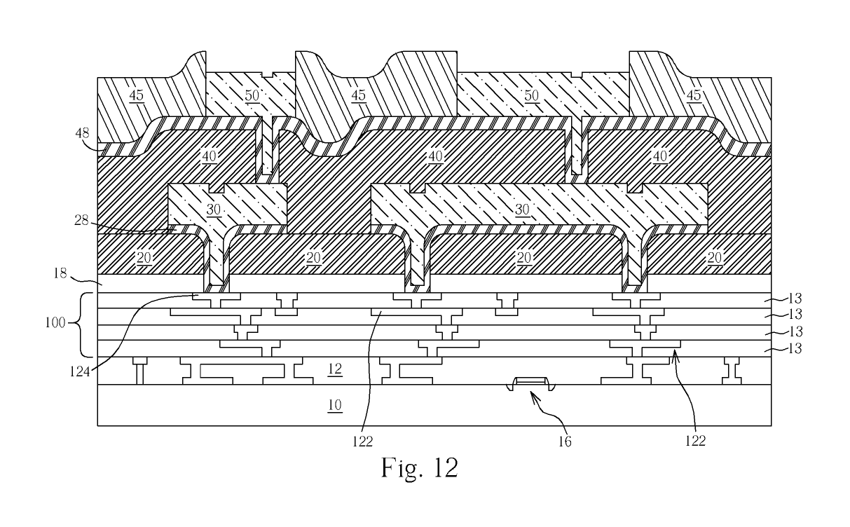

As shown in FIG. 12, an additive metal wire pattern 50 is next formed by electroplating or electroless plating methods, to a thickness of about 1-30 μm, preferably 2-8 μm. The additive metal wire pattern 50 may be gold, copper, Cu/Ni, or silver. In a case that Cu/Ni is used as the additive metal wire pattern 30, the nickel layer has a thickness of about 0.5-5 μm, preferably 1-3 μm. In a case that Au is used as the additive metal wire pattern 30, the Au layer has a thickness of about 1-30 μm, preferably 2-8 μm.

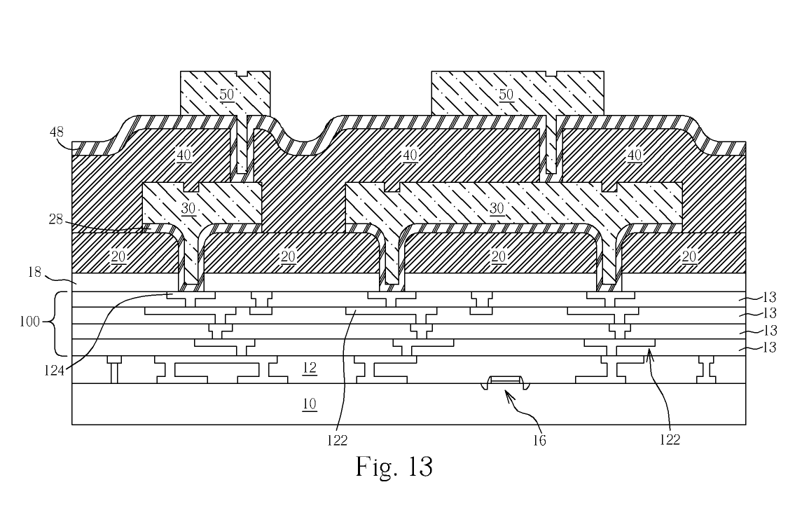

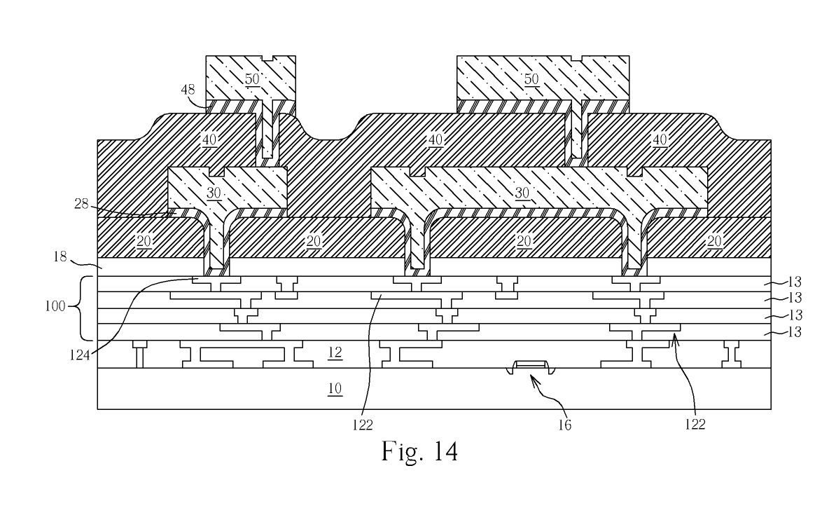

As shown in FIG. 13, likewise, the photoresist mask 45 is removed. After removing the photoresist mask 45, as shown in FIG. 14, the adhesion/barrier/seed layer 48 not covered by the additive metal wire pattern 50 is removed by dry etching methods. Alternatively, the adhesion/barrier/seed layer 48 may be etched by using wet etching, which forms an undercut recess under the additive metal wire pattern 50.

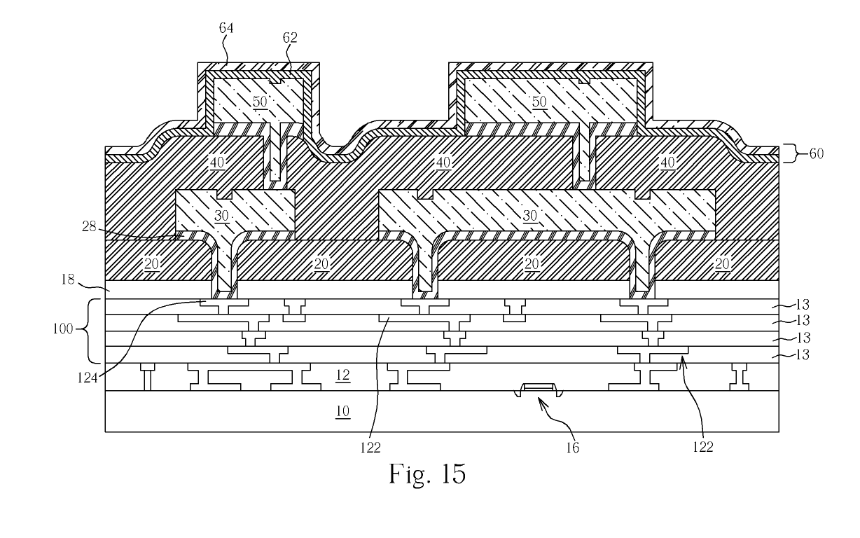

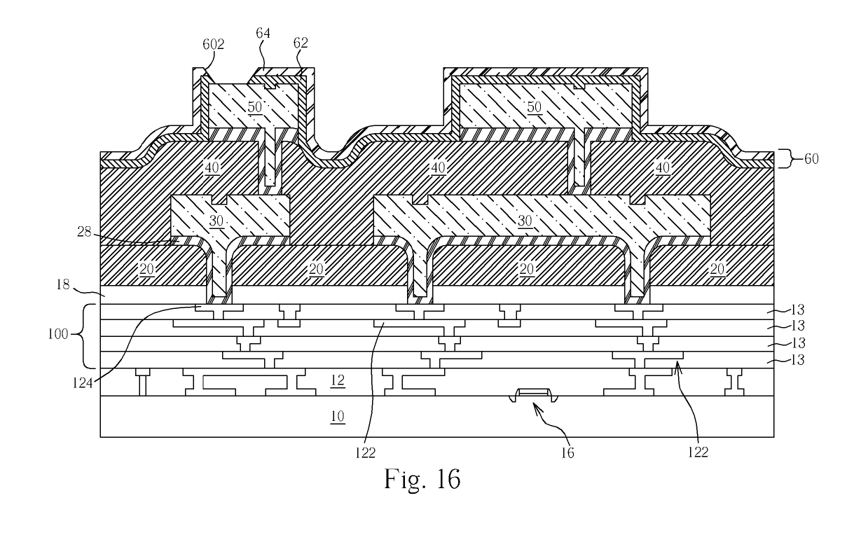

As shown in FIG. 15, a final passivation layer 60 is needed to cover the entire interconnection scheme so as to avoid contamination and moisture from the ambient. The passivation layer comprises a lower silicon oxide or oxy-nitride layer 62 and an upper silicon nitride layer 64. The passivation layer may be selected from the group consisting of silicon oxides, silicon nitrides, silicon oxy-nitrides, phosphorus doped glass silicates, silicon carbides and any combination thereof. The passivation layer can prevent the damage caused by scratching. For example, the passivation layer 60 may comprise a first inorganic dielectric layer such as an oxide layer deposited by plasma-enhanced chemical vapor deposition (PECVD). As shown in FIG. 16, openings 602 may be made through the passivation layer 60 to make external connection to the coarse metal line 50 for solder bump, gold bump, or wire bonding. The openings 602 in the passivation layer 60 may be formed using lithographic processes and etching process.

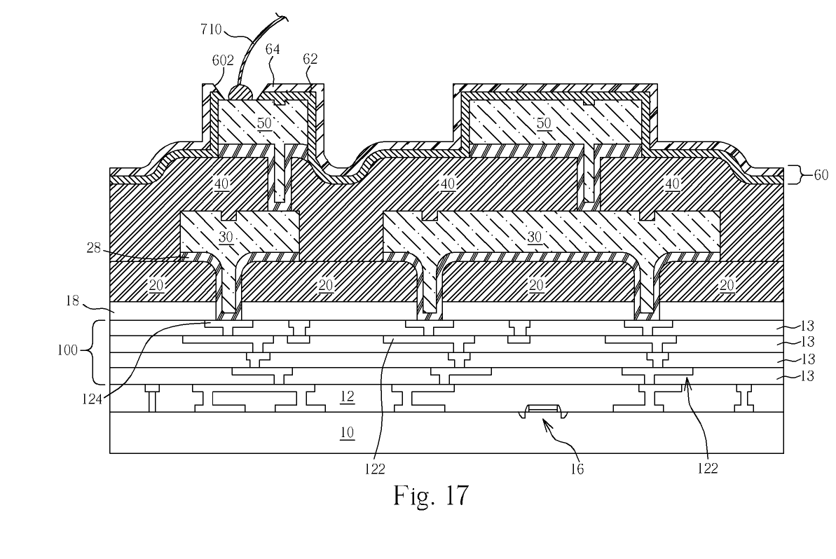

As shown in FIG. 17, after the formation of the openings 602 in the passivation layer 60, the exposed portion of coarse metal line 50 is wire bonded, as indicated by numeral number 710, in order to connect with an external circuit (not shown) such as a semiconductor chip, a printed circuit ceramic board or a glass substrate.

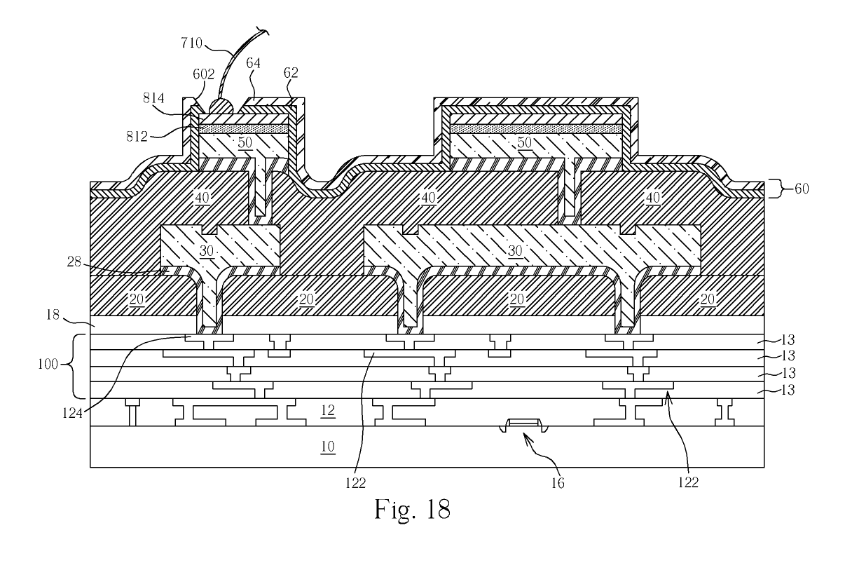

As shown in FIG. 18, in another preferred embodiment of this invention, the coarse metal line 50 comprises copper layer, a nickel layer 812 on top of the copper layer, and a bonding layer 814 on the nickel layer 812. The bonding layer 814 comprises Sn/Pb alloys, Sn/Ag alloys, Sn/Ag/Cu alloys, Pb-free solder, Au, Pt and Pd. After the formation of the openings 602 in the passivation layer 60, the exposed portion of coarse metal line 50 is wire bonded, as indicated by numeral number 710, in order to connect with an external circuit (not shown) such as a semiconductor chip, a printed circuit ceramic board or a glass substrate. The nickel layer 812 may be formed using plating methods.

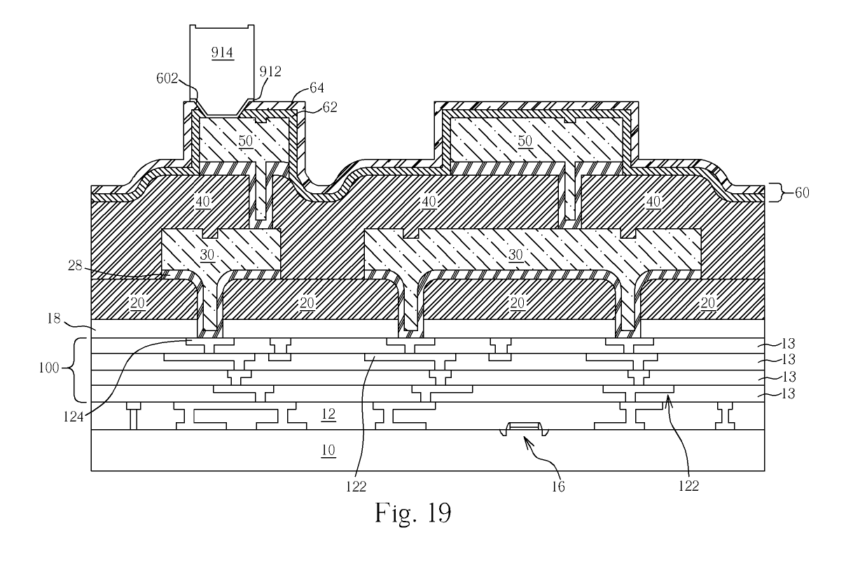

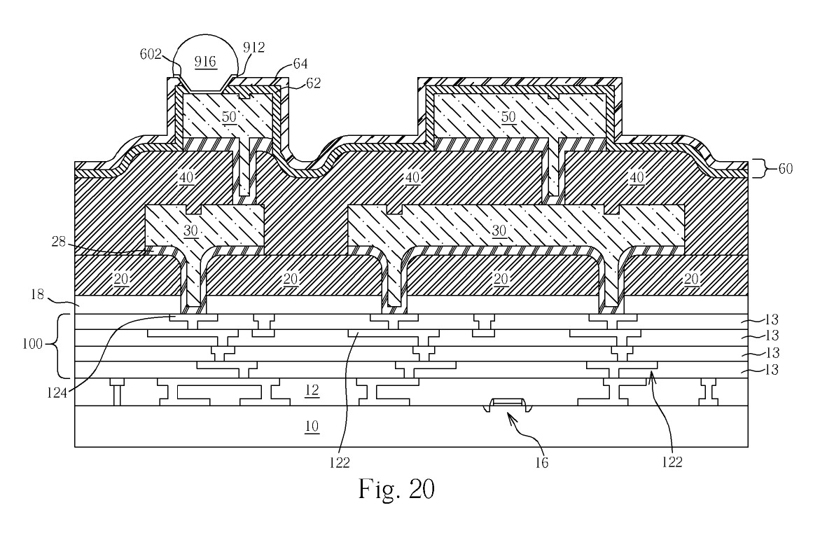

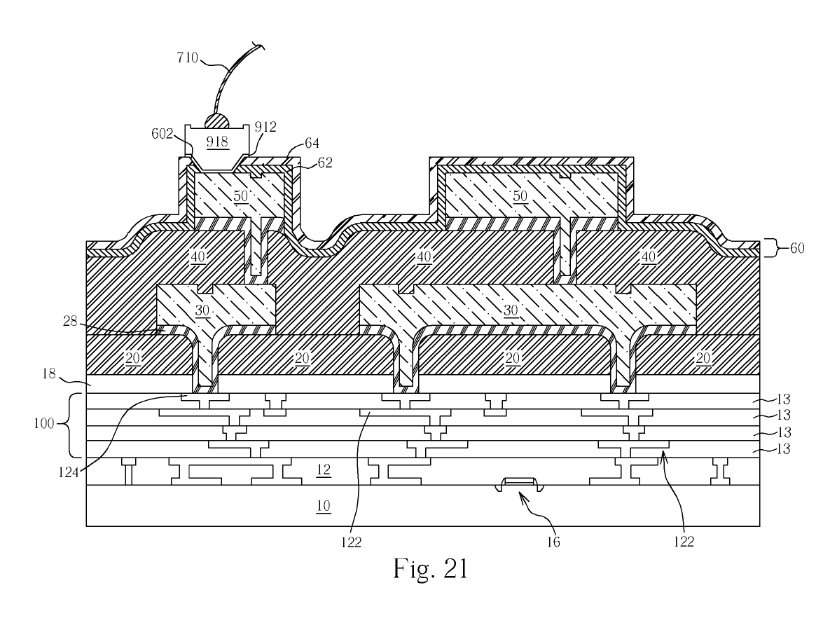

As shown in FIGS. 19 and 20, in still another preferred embodiment of this invention, an under-bump metallurgy (UBM) layer 912 is provided to cover the opening 602. On the UBM layer 912, a gold bump 914 (FIG. 19), or solder pad 916 (FIG. 20) may be formed, wherein the gold bump 914 has a thickness of about 10-30 micrometers. Such bonding structure facilitates subsequent wire bonding or TAB bonding processes. As shown in FIG. 21, a wire bonding process is performed to form bonding wire 710 on a gold pad 918 on UBM 912, wherein the gold pad 918 has a thickness of about 1-15 micrometers.

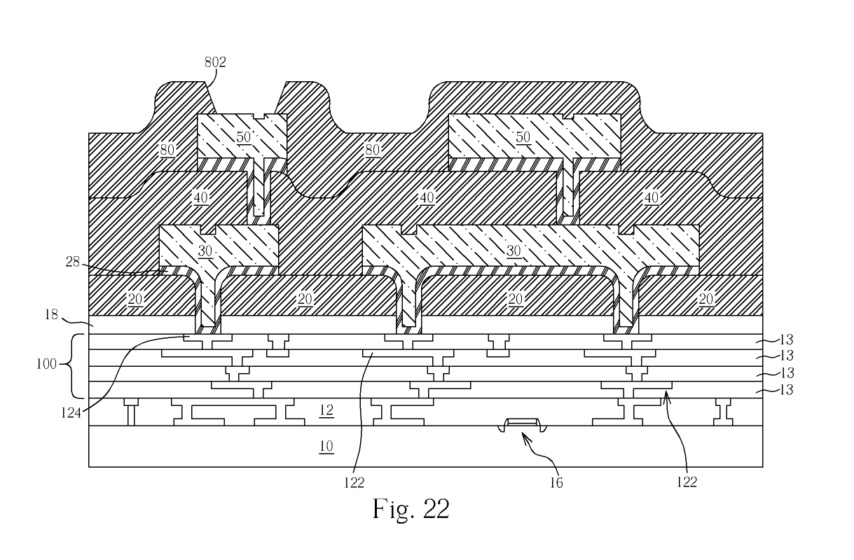

In another preferred embodiment of this invention, as shown in FIG. 22, the final passivation layer 60 as set forth in FIG. 15 may be replaced with a thick and hydrophobic polymer layer 80. The polymer layer 80 may be multiple coatings or cured. Suitable material for the polymer layer 80 includes polyimide, BCB, silicone elastomer, parylene or teflon, polycarbonate (PC), polysterene (PS), polyoxide (PO), poly polooxide (PPO) and epoxy-based materials.

The polymer layer 80 has a thickness of about 5000 angstroms to 30 micrometers (after curing). The thick polymer layer 80 can be coated in liquid form or can be laminated by dry film application. Openings 802 is defined by conventional processes of photolithography or can be created using laser (drill) technology to expose the coarse metal line 50 for solder bump, gold bump, or wire bonding.

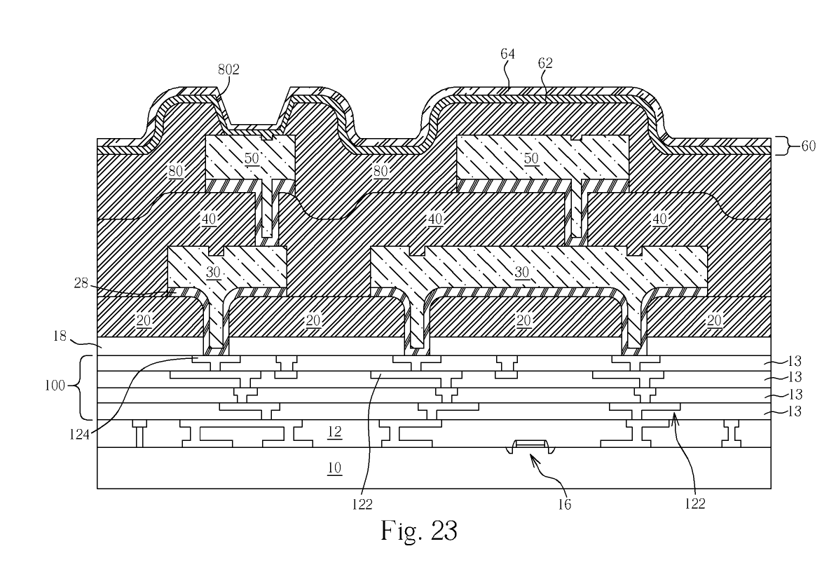

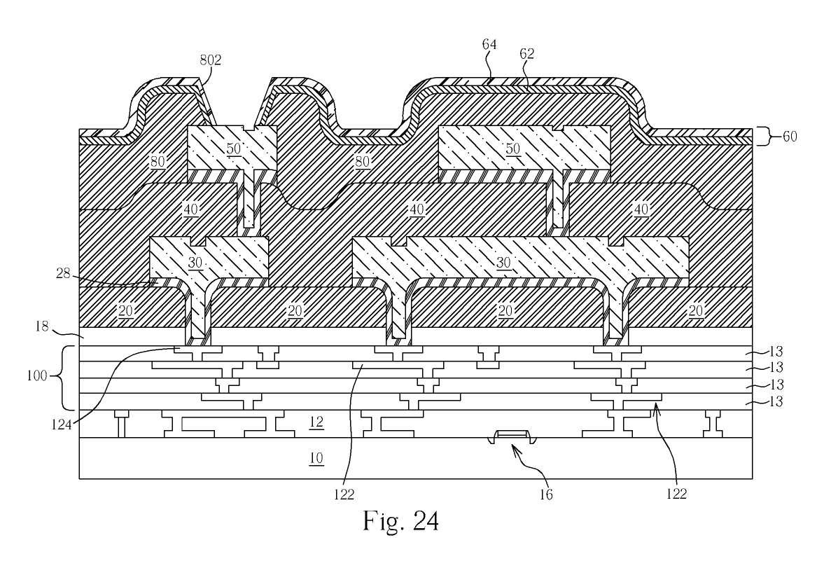

In still another preferred embodiment of this invention, as shown in FIGS. 23 and 24, after the formation of the embossing coarse metal line 50, a thick and hydrophobic polymer layer 80 is blanket deposited. The polymer layer 80 may be multiple coatings or cured. Suitable material for the polymer layer 80 includes polyimide, BCB, silicone elastomer, parylene or teflon, polycarbonate (PC), polysterene (PS), polyoxide (PO), poly polooxide (PPO) and epoxy-based materials. The polymer layer 80 has a thickness of about 5000 angstroms to 30 micrometers (after curing). The thick polymer layer 80 can be coated in liquid form or can be laminated by dry film application.

Openings 802 is defined by conventional processes of photolithography or can be created using laser (drill) technology. A final passivation layer 60 is deposited to cover the polymer layer 80 and the opening 802 so as to avoid contamination and moisture. The passivation layer 60 comprises a silicon oxide layer 62 and a silicon nitride layer 64. The passivation layer can prevent the damage caused by scratching. As shown in FIG. 24, the passivation layer 60 is etched to make external connection to the coarse metal line 50 for solder bump, gold bump, or wire bonding.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An integrated circuit chip comprising:
a semiconductor substrate;
a fine line metal interconnection structure overlying said semiconductor substrate;
a first embossing metal interconnection layer overlying said fine line metal interconnection structure;
a second embossing metal interconnection layer overlying said first embossing metal interconnection structure;
a polymer layer having a thickness of 3-30 microns between said first embossing metal interconnection layer and said second embossing metal interconnection layer; and
a patterned passivation layer overlying said second embossing metal interconnection structure, said patterned passivation layer comprising a plurality of openings exposing corresponding portions of said second embossing metal interconnection layer.

2. The integrated circuit chip of claim 1 further comprising a diffusion barrier layer overlying said fine line metal interconnection structure and underlying said first embossing metal interconnection layer.

3. The integrated circuit chip of claim 2 wherein said diffusion barrier layer comprises silicon nitride, silicon carbide and silicon oxynitride.

4. The integrated circuit chip of claim 2 wherein said diffusion barrier layer has a thickness of between about 1000 and 5000 Angstroms.

5. The integrated circuit chip of claim 1 wherein each layer of said fine line metal interconnection structure comprises aluminum or copper having a thickness of less than about 3 microns.

6. The integrated circuit chip of claim 1 wherein said first and second embossing metal interconnection layers comprise copper, silver, or gold.

7. The integrated circuit chip of claim 1 wherein said first and second embossing metal interconnection structure have a thickness of 3-25 microns.

8. The integrated circuit chip of claim 1 wherein said first and second embossing metal interconnection layers comprise a composite layer stack, formed of an adhesion/barrier layer, a seed layer over said adhesion/barrier layer, and a bulk metal layer over said seed layer.

9. The integrated circuit chip of claim 8 wherein said adhesion/barrier layer comprises TiW, TaN, Cr, Ti, Ta, or TiN.

10. The integrated circuit chip of claim 8 wherein said seed layer and said bulk metal layer are formed of the same metal comprising gold, silver, or copper.

11. The integrated circuit chip of claim 8 wherein said bulk metal layer has a thickness of 3-30 micrometers.

12. The integrated circuit chip of claim 1 wherein each layer of said fine line metal interconnection structure comprises a single bulk layer of aluminum.

13. The integrated circuit chip of claim 12 wherein each layer of said fine line metal interconnection structure further comprises an adhesion/barrier layer under said single bulk layer of aluminum.

14. The integrated circuit chip of claim 1 wherein each layer of said fine line metal interconnection structure is a layer of copper surrounded with a barrier layer.

15. The integrated circuit chip of claim 1 wherein said polymer layer comprises polyimide, benzocyclobutene (BCB), parylene and epoxy-based material.

16. The integrated circuit chip of claim 1 wherein said exposed portions of said second embossing metal interconnection layer through said openings are wire bonded to connected with an external circuit.

17. The integrated circuit chip of claim 16 wherein said external circuit comprises a semiconductor chip, a printed circuit ceramic board or a glass substrate.

18. The integrated circuit chip of claim 1 wherein said first or second embossing metal interconnection layer is made of copper, said second embossing metal interconnection layer is plated with a layer of gold.

19. The integrated circuit chip of claim 1 wherein said first or second embossing metal interconnection layer is made of copper, said second embossing metal interconnection layer is plated with a layer of nickel, and a bonding layer coated on the layer of nickel.

20. The integrated circuit chip of claim 19 wherein said bonding layer comprises Sn/Pb alloys, Sn/Ag alloys, Sn/Ag/Cu alloys, Pb-free solder, Au, Pt and Pd.

21. The integrated circuit chip of claim 1 wherein said passivation layer is selected from the group consisting of silicon oxides, silicon nitrides, silicon oxy-nitrides, phosphorus doped glass silicates, silicon carbides and any combination thereof.
